(19) United States
(12) Patent Application Publication
(10) Pub. No.: US 2026/0231822 A1
(43) Pub. Date: Aug. 6, 2026

(54) SEMICONDUCTOR PACKAGE AND METHOD OF MANUFACTURING THE SAME

(71) Applicant: Taiwan Semiconductor Manufacturing Company, Ltd., Hsinchu (TW)

(72) Inventors: Chung-Ming Weng, Taichung City (TW); Yu-Hao Chen, HsinChu City (TW); An-Jhih Su, Taoyuan City (TW); Yen-Liang Lin, Taichung City (TW); Tzuan-Horng Liu, Taoyuan City (TW)

(73) Assignee: Taiwan Semiconductor Manufacturing Company, Ltd., Hsinchu (TW)

(21) Appl. No.: 19/046,517

(22) Filed: Feb. 6, 2025

(51) Int. Cl. H01L 25/16; G02B 6/42; H01L 23/00; H01L 23/31; H01L 23/48

(52) U.S. Cl. CPC H10W 90/00; H10W 74/141; G02B 6/4214; H10W 20/20; H10W 70/09; H10W 70/60; H10W 90/10

(57) ABSTRACT

A semiconductor package provided herein includes a first redistribution circuitry structure, a photonic die, and electronic dies. The photonic die is disposed on the first redistribution circuitry structure, wherein an outer edge of the first redistribution circuitry structure is coplanar with an outer edge of the photonic die. The electronic dies are disposed on the first redistribution circuitry structure and electrically connected to the phonic die through the first redistribution circuitry structure. A method of fabricating the semiconductor die is also provided herein.

### BACKGROUND

The semiconductor industry has experienced rapid growth due to ongoing improvements in the integration density of a variety of electronic components (e.g., transistors, diodes, resistors, capacitors, etc.). Nowadays, photonic integrate circuit is emphasized since larger bandwidth and higher data transfer speeds are achieved. For the most part, improvement in integration density has resulted from iterative reduction of minimum feature size, which allows more components to be integrated into a given volume. However, packaging techniques of photonic integrate circuit is still developing.

### BRIEF DESCRIPTION OF THE DRAWINGS

FIG. 1 schematically illustrates a schematic planar view of a semiconductor package in accordance with some embodiments of the disclosure.

FIG. 2 schematically illustrates a schematic planar view of a semiconductor package in accordance with some embodiments of the disclosure.

FIG. 3 schematically illustrates a schematic planar view of a semiconductor package in accordance with some embodiments of the disclosure.

FIG. 4 schematically illustrates a schematic planar view of a semiconductor package in accordance with some embodiments of the disclosure.

FIG. 5 schematically illustrates a schematic planar view of a semiconductor package in accordance with some embodiments of the disclosure.

FIG. 6 schematically illustrates a cross-sectional view of a semiconductor package in accordance with some embodiments of the disclosure.

FIG. 7 schematically illustrates several process steps of a method of fabricating a semiconductor package.

FIG. 8 schematically illustrates a scheme of coupling the photonic die in the semiconductor package with an optical fiber.

FIG. 9A and FIG. 9B schematically illustrate schemes of coupling the photonic die the semiconductor package with an optical fiber.

FIG. 10 schematically illustrates a cross-sectional view of a semiconductor package in accordance with some embodiments of the disclosure.

FIG. 11 schematically illustrates several steps of a method of fabricating a semiconductor package in accordance with some embodiments.

FIG. 12 schematically illustrates a cross-sectional view of a semiconductor package in accordance with some embodiments of the disclosure.

FIG. 13 is a schematic planar view of a semiconductor package in accordance with some embodiments of the disclosure.

FIG. 14 schematically illustrates a scheme of coupling the photonic die in the semiconductor package with an optical fiber.

FIG. 15 schematically illustrates a scheme of coupling the photonic die in the semiconductor package with an optical fiber.

FIG. 16 schematically illustrates a method of fabricating the integrated optical structure depicted in FIG. 15.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

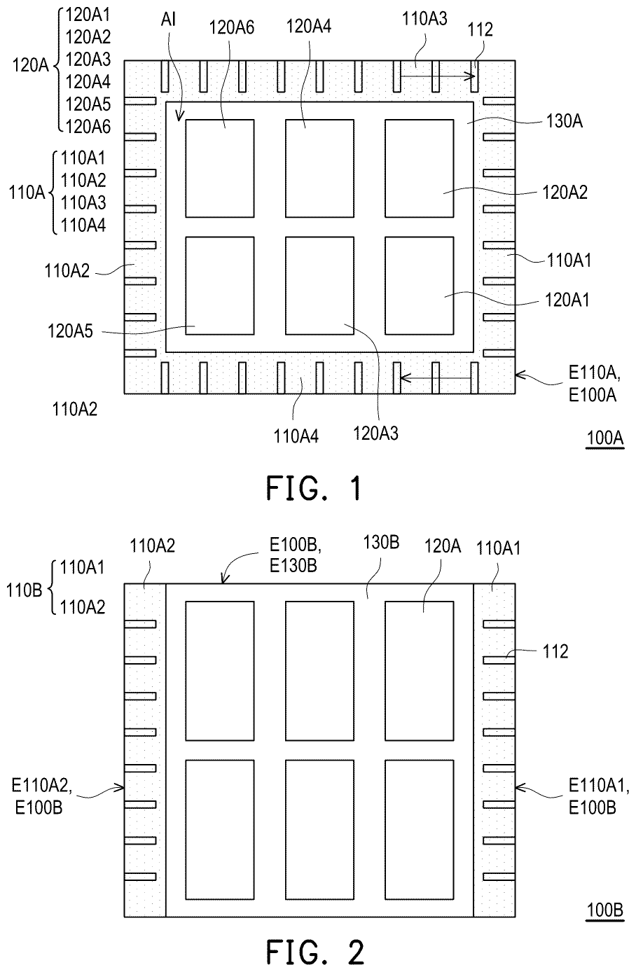

FIG. 1 schematically illustrates a schematic planar view of a semiconductor package in accordance with some embodiments of the disclosure. A semiconductor package 100A shown in FIG. 1 includes a photonic die 110A, electronic dies 120A and an encapsulation insulation 130A. The photonic die 110A is disposed along the periphery of the semiconductor package 100A, and in the planar view, the edge E100A of the semiconductor package 100A overlaps the outer edge E110A of the photonic die 110A. In the embodiment, the photonic die 110A includes linear periphery portions 110A1~110A4 to form a ring-like top view shape extending along a periphery of the semiconductor package 100A and surrounds an inner area AI. The electronic dies 120A are arranged in the inner area AI demarcated by the photonic die 110A. The encapsulation insulation 130A is disposed in the inner area AI to laterally surround and encapsulate the electronic dies 120A. In addition, the encapsulation insulation 130A may overlap the gap between the photonic dies 110A and the electronic dies 120A. In the embodiment, the outline of the semiconductor package 100A may be determined by the photonic die 110A.

For descriptive purpose, FIG. 1 shows the disposition relationship of the photonic die 110A, the electronic dies 120A and the encapsulation insulation 130A in the planar view. However, some of the design of the semiconductor package 100A may not be presented in FIG. 1. For example, the semiconductor package 100A may further include other components overlapping the photonic die 110A, the electronic dies 120A and the encapsulation insulation 130A, such as one or more redistribution circuitry structure, and/or other dies. In some embodiments, the electronic dies 120A and the photonic die 110A may be located at different levels in the thickness direction and the encapsulation insulation 130A surrounding the electronic dies 120A may overlap the photonic die 110A.

The photonic die 110A is a photonic integrated circuit (PIC) die. The photonic die 110A includes four linear periphery portions 110A1~110A4 and optical transmission structures 112 formed therein. The linear periphery portion 110A1 and the linear periphery portion 110A2 are opposite to each other and the linear periphery portion 110A3 and the linear periphery portion 110A4 are opposite to each other. In addition, the four linear periphery portions 110A1~110A4 are connected to form a rectangular ring. The optical transmission structures 112 formed in the four linear periphery portions 110A1~110A4 may extend in a direction intersecting the extending direction of the respective linear periphery portions 110A1~110A4. The terminal of each of the optical transmission structures 112 may extend to reach or proximate to the outer edge E110A of the photonic die 110A. The optical transmission structures 112 serve as optical input/output (I/O) structures for the semiconductor package 100A. In other words, the optical transmission structures 112 enable the transmission of optical signals from the semiconductor package 100A to the external devices and/or from the external devices to the semiconductor package 100A. In some embodiments, the optical transmission structures 112 in the photonic die 110A may include one or more optical waveguide, one or more optical grating, or the like. The photonic die 110A also include optical components such as one or more optical resonator, one or more optical modulator. In addition, the photonic die 110A also includes non-illustrated electronic components such as transistors or other device to build a circuitry so that the photonic die 110A can detect the optical signals, converting between the optical signals and the electrical signals and transmitting the electrical signals.

The electronic dies 120A are electrically connected to the photonic die 110A. Each of the electronic dies 120A may include transistors therein to enable the required circuitry function. Each of the electronic dies 120A may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In the embodiment, FIG. 1 shows six electronic dies 120A1~120A6 as an example. Among the electronic dies 120A1~120A6, one, for example, the electronic die 120A1, is electrically connected between the photonic die 110A and others, for example, the electronic dies 120A2~120A6. The electronic die 120A1 accompanying with the photonic die 110A may covert the received optical signals to the electronic signals and transmits the generated electronic signals to the electronic dies 120A2~120A6. Specifically, the optical signals may be received by the optical transmission structures 112 in the photonic die 110A. In some embodiment, one or more photodiode may be integrated in the semiconductor package 100A to provide a light source. As such, the photodiode may be disposed in the inner area AI surrounded by the photonic die 110A.

In the embodiment, the semiconductor package 100A may have a wafer-level or panel-level size. For example, a top view shape of the semiconductor package 100A may be a rectangle (square) with a size of 300 mm×300 mm or more, or a circle with a diameter of 300 mm or more. Therefore, the semiconductor package 100A is a package that integrates one or more logic die, one or more memory die, one or more photonic die, etc. in a wafer-level or panel-level size, which may be considered as a system on wafer (SOW) or a system on panel (SOP) package. In the embodiment, the photonic die 100A extending along the periphery of the semiconductor package 100A has a large size to provide plenty of transmission channels for the optical signals, which enables a high bandwidth design and is advantageous to the development of the technologies such as the Internet of Things (IoT), the Artificial Intelligence (AI), the high performance computing (HPC), etc.

FIG. 2 schematically illustrates a schematic planar view of a semiconductor package in accordance with some embodiments of the disclosure. A semiconductor package 100B includes a photonic die 110B, electronic dies 120A and an encapsulation insulation 130B. In the embodiment, the photonic die 110B includes two linear periphery portions 110A1 and 110A2 arranged along the periphery of the semiconductor package 100B. The linear periphery portions 110A1 and 110A2 of the photonic die 110B are in parallel and extend along two opposite sides of the semiconductor package 100B, but in other embodiments, the linear periphery portions 110A1 and 110A2 may extend along two connected sides of the semiconductor package 100B. The electronic dies 120A and the encapsulation insulation 130B are disposed between the two linear periphery portions 110A1 and 110A2 of the photonic die 110B. The encapsulation insulation 130B surrounds the electronic dies 120A and extends between the photonic die 110B and the electronic dies 120A.

In the embodiment, the outer edge E110B1 of the linear periphery portions 110A1 along the extending direction and the outer edge E110B2 of the linear periphery portions 110A2 along the extending direction overlap respective parts of the edge E100B at two opposite sides of semiconductor package 100B. The outer edge E130B of the encapsulation insulation 130B and the edge E100B of the semiconductor package 100B are partially overlapped at the other two opposite sides of semiconductor package 100B. In addition, the outer edges outer edge E110B1 and E110B2 of the linear periphery portions 110A1 and 110A2 along a direction intersecting the extending direction are connected the outer edge E130B of the encapsulation insulation 130B. Accordingly, the outline of the semiconductor package 100B in the planar view may be determined by the encapsulation insulation 130B and the two linear periphery portions 110A1 and 110A2 of the photonic die 110B.

In the embodiment, the two linear periphery portions 110A1 and 110A2 of the photonic die 110B are located at two opposite sides of the semiconductor package 100B and laterally spaced from each other. The two linear periphery portions 110A1 and 110A2 of the photonic die 110B may be electrically connected to a common one or different ones of the electronic dies 120A. The photonic die 110B provides the same function as the photonic die 110A FIG. 1 and thus the functions of the photonic die 110B may refer to the description of the embodiment of FIG. 1. FIG. 2 is used for illustrating the disposition relationship of the photonic die 110B, the electronic dies 120A and the encapsulation insulation 130B, but the design of the semiconductor package 100B is not limited thereto. In some embodiments, one of the two linear periphery portions 110A1 and 110A2 of the photonic die 110B may be omitted as long as the transmission channels provided by the photonic die 110B is sufficient for the semiconductor package. In some embodiments, the semiconductor package 100B may include further components not shown in FIG. 2.

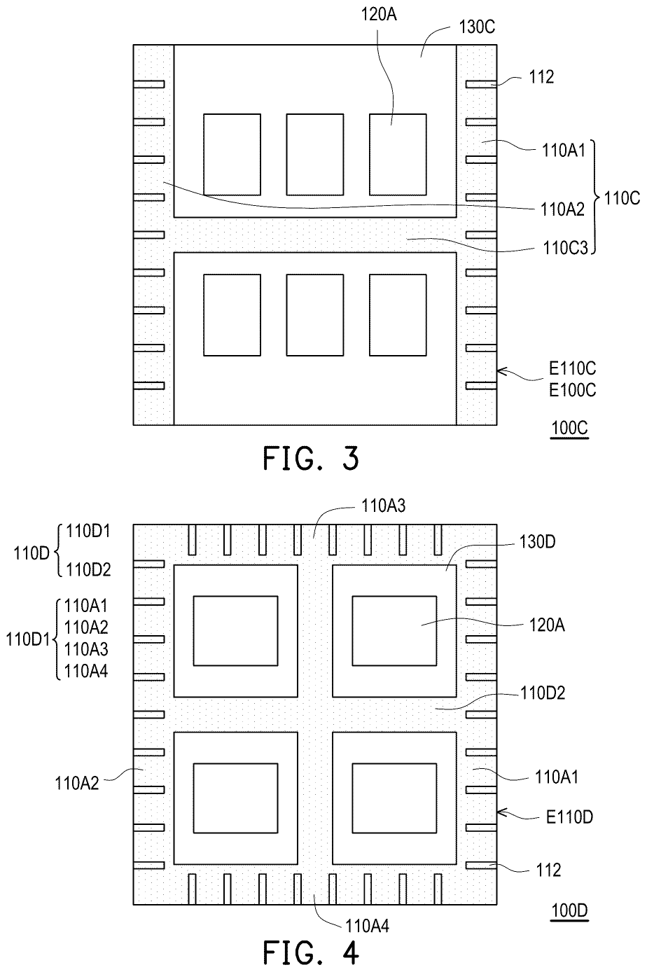

FIG. 3 schematically illustrates a schematic planar view of a semiconductor package in accordance with some embodiments of the disclosure. A semiconductor package 100C includes a photonic die 110C, electronic dies 120A and an encapsulation insulation 130C. In the embodiment, the photonic die 110C includes two linear periphery portions 110A1 and 110A2 and a connection portion 110C3 extending between the two linear periphery portions 110A1 and 110A2. The designs of the electronic dies 120 and the two linear periphery portions 110A1 and 110A2 may refer to the descriptions of the previous embodiments of FIG. 1 and FIG. 2. Specifically, the two linear periphery portions 110A1 and 110A2 are located opposite to each other and arranged along the periphery of the semiconductor package 100B to define parts of the outline of the semiconductor package 100C in the planar view. In the embodiment, the photonic die 110C may include the optical transmission structures 112 disposed in the two linear periphery portions 110A1 and 110A2 and the optical transmission structures 112 extend to reach or proximate to the outer edge E110C of the photonic die 110C.

The connection portion 110C3 extends in a direction intersecting the extending directions of the two linear periphery portions 110A1 and 110A2 and connects to the two linear periphery portions 110A1 and 110A2 to form a “H-like” pattern in the planar view. The electronic dies 120A may be disposed at opposite sides of the connection portion 110C3 of the photonic die 110C in the planar view. The encapsulation insulation 130C may include two portions located at two opposite sides of the connection portion 110C3 and extend to reach the edge E100C of the semiconductor package 100C. In some embodiments, the connection portion 110C3 may be connected to the electronic dies 120A located in the center portion of the semiconductor package 100C without a long-distance transmission routing, which improves the flexibility of arranging the electronic dies 120A. In some embodiments, the connection portion 110C3 may include electronic components for providing the required electronic/electrical function.

FIG. 4 schematically illustrates a schematic planar view of a semiconductor package in accordance with some embodiments of the disclosure. A semiconductor package 100D includes a photonic die 110D, electronic dies 120A and an encapsulation insulation 130D. In the embodiment, the photonic die 110C includes a periphery portion 110D1 and an inner portion 110D2. The periphery portion 110D1 has a shape substantially the same as the photonic die 110A shown in FIG. 1 and includes linear periphery portions 110A1~110A4. The photonic die 110D may include a plurality of optical transmission structure 112 disposed in the linear periphery portions 110A1~110A4. The inner portion 112D2 has a cross shape and divide the semiconductor package 100D into four regions. Four electronic dies 120A may be disposed in the four regions, respectively, but the disclosure is not limited thereto. The encapsulation insulation 130D is disposed to extend between the electronic dies 120A and the photonic die 110D in the four regions divided by the inner portion 110D2 of the photonic die 110D. The periphery portion 110D1 includes four linear periphery portions 110A1~110A4 extending along four sides of the semiconductor die 100D and an outer edge E110D of the photonic die 110D extends along the edge of the semiconductor package 100D.

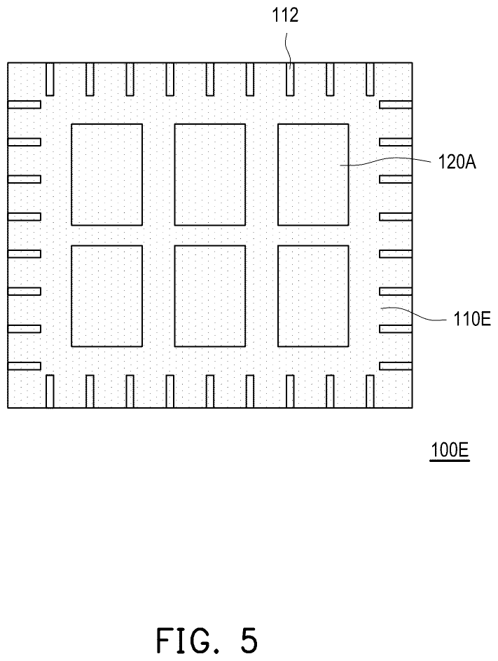

FIG. 5 schematically illustrates a schematic planar view of a semiconductor package in accordance with some embodiments of the disclosure. A semiconductor package 100E includes a photonic die 110E and electronic dies 120A. For illustration purpose, some components of the semiconductor package 100E are omitted. For example, the semiconductor package 100E further include at least an encapsulation insulation that surrounds the electronic dies 120A to encapsulate the electronic dies 120A in an integrated package. In the embodiment of FIG. 5, the photonic die 110E may have a planar size identical to the semiconductor package 100E and include the optical transmission structures 112 arranged along the periphery of the photonic die 110E. The photonic die 110E may cover the entire area of the semiconductor package 100E in the planar view. The electronic dies 120A are disposed on and overlap the photonic dies 110E in the planar view.

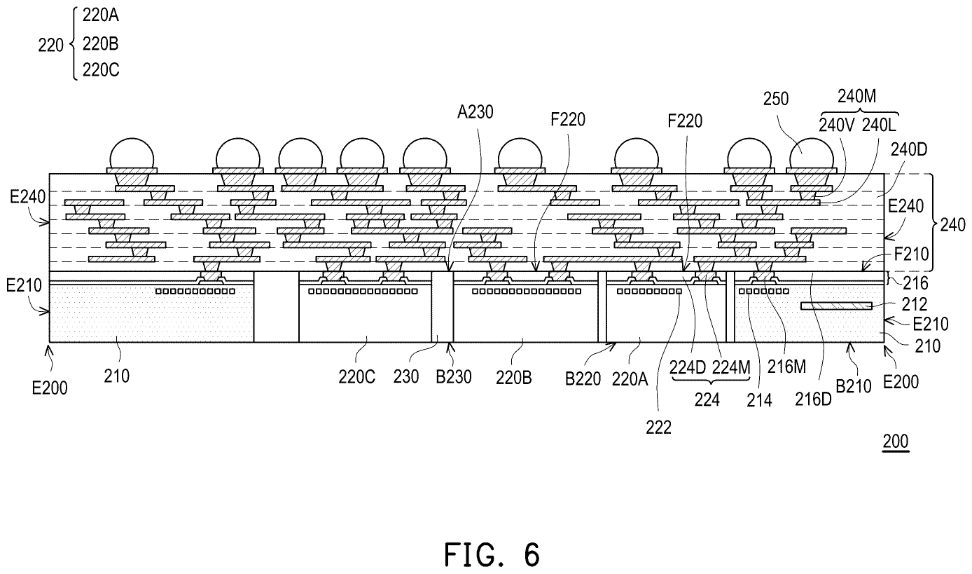

FIG. 6 schematically illustrates a cross-sectional view of a semiconductor package in accordance with some embodiments of the disclosure. A semiconductor package 200 shown in FIG. 6 includes a photonic die 210, electronic dies 220, an encapsulation insulation 230, a redistribution circuitry structure 240 and conductive connectors 250. The photonic die 210, the electronic dies 220, the encapsulation insulation 230 are disposed on a side of the redistribution circuitry structure 240 and the conductive connectors 250 are disposed on an opposite side of the redistribution circuitry structure 240. In the embodiment, an outer edge E240 of the first redistribution circuitry structure 240 is coplanar with an outer edge E210 of the photonic die 210. The outline of the semiconductor package 200 may be determined by the outer edge E210 of the photonic die 210 and the outer edge E240 of the first redistribution circuitry structure 240. In other words, the photonic die 210 is exposed at the edge E200 of the semiconductor package 210. The electronic dies 220 are located at the inner region of the semiconductor package 200. For example, the electronic dies 220 are further away from the edge E200 of the semiconductor package 200 than the photonic die 210 in a lateral direction.

The photonic die 210 includes an optical transmission structure 212, an electronic component structure 214 and an interconnect structure 216 formed in/on a semiconductor substrate such as a silicon substrate. The photonic die 210 may be considered as a silicon photonic, SiPh. The optical transmission structure 212 may include one or more waveguide, one or more optical grating, other optical components, or a combination thereof. The optical transmission structure 212 may extend to proximate to or reach the outer edge E210 of the photonic die 210 for optically coupling to an external device such as an optical fiber. The electronic component structure 214 includes one or more transistor formed in/on the silicon substrate of the photonic die 210 by implementing the front end of line (FEOL) of the semiconductor manufacturing process. The electronic component structure 214 may construct a circuitry component capable of detecting the optical signals and converting between the optical signals and the electronic signals. In some embodiments, the electronic component structure 214 may include a detector, or the like. The interconnect structure 216 is disposed at a front surface F210 of the photonic die 210 and provides electrical transmission features for the electronic component structure 214 transmitting to the redistribution circuitry structure 240. For example, the interconnect structure 216 includes one or more layers of metal feature 216M embedded in one or more dielectric feature 216D. In some embodiments, the interconnect structure 216 may be fabricated through the back end of line (BEOL) of the semiconductor manufacturing process. The photonic die 210 may further one or more optical resonator, one or more optical modulator or the like that is not illustrated.

Each of the electronic dies 220 includes an electronic component structure 222 and an interconnect structure 224 formed in/on a semiconductor substrate. The electronic component structure 222 include at least one transistor, at least one other electronic component, or a combination thereof. The electronic component structure 222 may be fabricated by implementing the front end of line (FEOL) of the semiconductor manufacturing process. The interconnect structure 224 is disposed at a front surface F220 of the respective electronic die 220 and provide electrical transmission features for the electronic component structure 222 transmitting to the redistribution circuitry structure 240. The interconnect structure 224 includes one or more layers of metal feature 224M embedded in one or more dielectric feature 224D. In some embodiments, the interconnect structure 224 may be fabricated through the back end of line (BEOL) of the semiconductor manufacturing process.

Here, a side of a semiconductor die with the electronic components fabricated by FEOL of the semiconductor manufacturing process is considered as a front surface while the opposite side of the semiconductor die is considered as a back surface. The front surface F210 of the photonic die 210 and the front surface F220 of the respective electronic die 220 may be arranged at a common level as the surface A230 of the encapsulation insulation 230 while the back surface B210 of the photonic die 210 and the back surface B220 of the respective electronic die 220 may be arranged at a common level as the opposite surface B230 of the encapsulation insulation 230. In the embodiment, the photonic die 210 and the electronic dies 220 are disposed on the redistribution circuitry structure 240 in a manner that the front surface F210 of the photonic die 210 and the front surface F220 of the respective electronic die 220 face the redistribution circuitry structure 240. The redistribution circuitry structure 240 is disposed on a substantially flat plane defined by the front surface F210 of the photonic die 210, the front surface F220 and the surface A230 of the encapsulation insulation 230.

The electronic dies 220 may provide various functions. For example, in the embodiment, the electronic die 220A may be an electronic die connected between the photonic die 210 and other electronic dies 220, while each of the electronic die 220B and the electronic die 220C may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The redistribution circuitry structure 240 include a dielectric structure 240D and multiple layers of metal features 240M formed in the dielectric structure 240D. In some embodiments, the dielectric structure 240D includes multiple dielectric layers made of a polymer material. The metal features 240M may include metal line features 240L and metal via features 240V. The metal line features 240L may linearly extend in a planar direction to distribute in a desired routing path. The metal via features 240V may connected the metal line features 240L at different levels. Accordingly, the redistribution circuitry structure 240 establish various electric transmission paths for various components. In the embodiment, the photonic die 210 and the electronic dies 220 are disposed at a common side of the redistribution circuitry structure 240 and the conductive connectors 250 are dispose at the opposite side of the redistribution circuitry structure 240. One or more of the photonic die 210 and the electronic dies 220 may be electrically connected to the conductive connectors 250 through the redistribution circuitry structure 240. In addition, the photonic die 210 and the electronic dies 220 may be electrically connected to one another through the redistribution circuitry structure 240. The semiconductor package 200 integrating the photonic die 210 and the electronic dies 220 on the redistribution circuitry structure 240 with the encapsulation insulation 230 has a compact volume since no substrate is required.

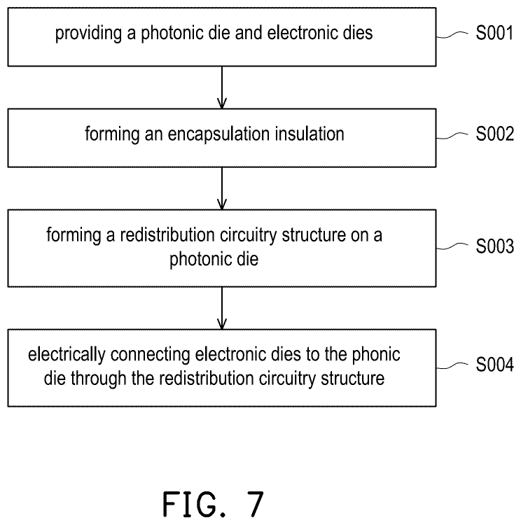

FIG. 7 schematically illustrates several process steps of a method of fabricating a semiconductor package. The semiconductor package 200 may be fabricated by the following steps. Referring to FIG. 6 and FIG. 7, in some embodiments, in the step S001, the photonic die 210 and the electronic dies 220 that are known good dies and finished in advance are provided and temporally attached on a carrier substrate (not illustrate). The photonic die 210 and the electronic dies 220 are oriented in a manner that the front surface F210 of the photonic die 210 and the front surfaces E220 of the electronic dies 220 face the carrier substrate. In the step S002, the encapsulation insulation 230 is formed to surround the electronic dies 220 and fill the gaps between the photonic die 210 and the electronic dies 220, such that the photonic die 210 and the electronic dies 220 are laterally encapsulated by the encapsulation insulation 230 to form an integrated structure prior to forming the redistribution circuitry structure 240. A planarization process is optionally performed so that the back surface B210 of the photonic die 210, the back surfaces B220 of the electronic dies 220 and the surface B230 of the encapsulation insulation 230 are coplanar at a common level. The carrier substrate is then removed from the integrated structure to expose the front surface E210 of the photonic die 210, the front surfaces F220 of the electronic die 220 and the surface A230 of the encapsulation insulation 230. Thereafter, in the step S003, the redistribution circuitry structure 240 is formed on the front surface E210 of the photonic die 210, the front surfaces F220 of the electronic die 220 and the surface A230 of the encapsulation insulation 230 so that the photonic die 210 and the electronic dies 220 are disposed on a common side of the redistribution circuitry structure 240. Upon forming the redistribution circuitry structure 240 on the photonic die 210 and the electronic dies 220, the electronic dies 220 may be electrically connected to the photonic die 210 through the redistribution circuitry structure 240, as the step S004. The conductive connectors 250 are then formed on the opposite side of the redistribution circuitry structure 240. Finally, the semiconductor package 220 integrating the photonic die 210 and the electronic dies 220 in a wafer (panel)-level fan-out package is formed.

In the semiconductor package 220, the electronic dies 220 and the photonic die 210 are connected to the redistribution circuitry structure 240 at a common level. The redistribution circuitry structure 240 provides electrical transmission routing paths for transmitting the electric signals in required paths. The photonic die 210 is electrically connected to the redistribution circuitry structure 240, and the electronic dies 220 are also electrically connected to the redistribution circuitry structure 240. In the embodiment, at least one of the electronic dies 220 is electrically connected to the photonic die 210 through the redistribution circuitry structure 240. In the embodiment, the encapsulation insulation 230 is disposed on the redistribution circuitry structure 240 and located between the electronic dies 220 and the photonic die 210. As shown in FIG. 6, the semiconductor package 200 is a package integrating the photonic die 210 and multiple electronic dies 220 without a substrate or a circuit board. In some embodiments, the semiconductor package 200 may be implemented to have the top view structure as shown in any of the embodiments of FIG. 1~4. For example, the photonic die 210 may include the linear periphery portion 110A1/110A2/110A3/110A4 that extends along the periphery of the semiconductor package 200 at one or more side. The semiconductor package 200 may have a wafer-level size or panel-level size. For example, a top view shape of the semiconductor package 200 may be a rectangle (square) with a size of 300 mm×300 mm or more, or a circle with a diameter of 300 mm or more.

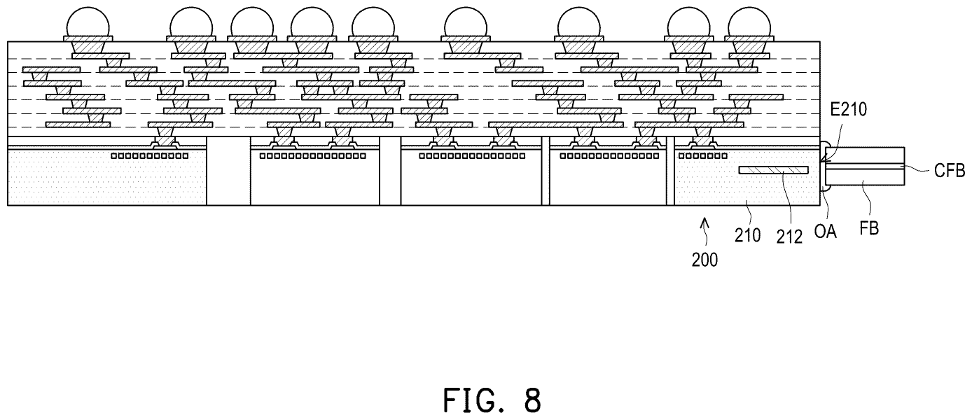

The semiconductor package 200 includes the photonic die 210 disposed along the periphery to enable the I/O transmission of the optical signals through the edge. FIG. 8 schematically illustrates a scheme of coupling the photonic die in the semiconductor package with an optical fiber. As shown in FIG. 8, an optical fiber FB may be attached/connected to the semiconductor package 200 though an optical adhesive OA. Specifically, the optical fiber FB is attached to the outer edge E210 of the photonic die 210. The optical fiber FB is positioned so that the optical coupling between the core CFB of the optical fiber FB and the optical transmission structure 212 formed in the photonic die 210 is optimized.

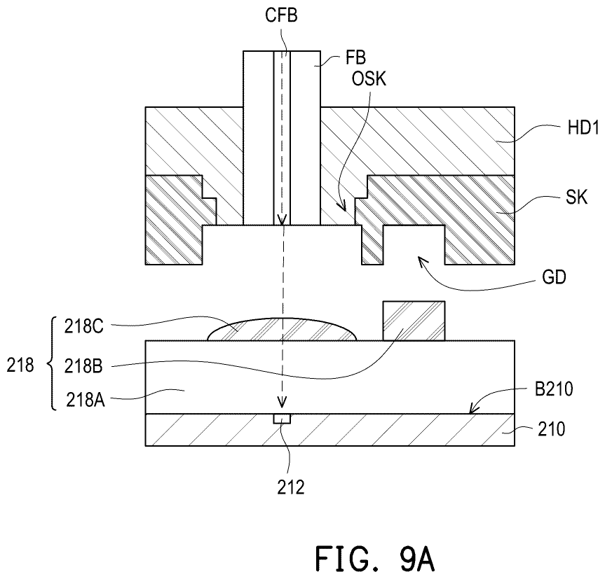

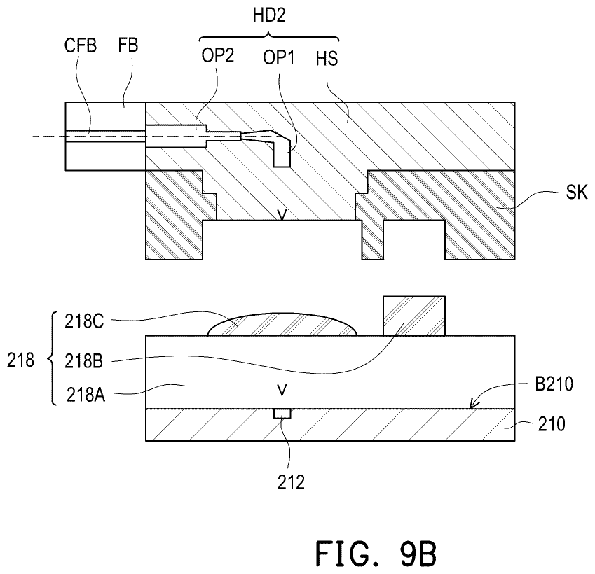

FIG. 9A and FIG. 9B schematically illustrates schemes of optical coupling between the semiconductor package and an external device at the back side of the photonic die. As shown in FIG. 9A, a portion of the photonic die 210 of the semiconductor package 200 is provided. A coupling structure 218 is disposed at the back side B210 of the photonic die 210. The coupling structure 218 includes a base 218A, a guiding member 218B and a lens member 218C. The guiding member 218B and the lens member 218C are disposed on the base 218A and protruded from the base 218A in a direction away from the photonic die 210. The lens member 218C is disposed corresponding the optical transmission structure 212 of the photonic die 210. In the embodiment, the optical fiber FB is carried by a fiber holder HD1 and a socket SK is provided to connect the fiber holder HD1 to the coupling structure 218. The socket SK may have a guiding structure GD corresponding to the guiding member 218B and an opening OSK accommodating the fiber holder HD1. As such, the socket SK is attached to the coupling structure 218 by assembling the guiding structure GD to the guiding member 218B. After the socket SK is attached to the coupling structure 218, the core CFB of the optical fiber FB may be oriented to direct to the lens member 218C of the coupling structure 218 and optically coupled to the photonic die 210. In the embodiment, the coupling structure 218 is made of a transparent material allowing the optical signal to pass through it. In some embodiments, the socket SK may be attached to the coupling structure 218 through an optical adhesive material.

In FIG. 9B, the coupling structure 218 is disposed at the back side B210 of the photonic die 210, and the socket SK is provided. Here, the coupling structure 218 and the socket SK may refer to those depicted in FIG. 9A. In the embodiment, the optical fiber FB is hold by a interface structure HD2. The interface structure HD2 includes a housing HS and optical components OP1 and OP2. The optical components OP1 and OP2 are equipped in the housing HS. In some embodiments, the optical component OP1 is a prism that is able to turning and/or refracting the path of a light beam and the optical component OP2 is an optical coupler. The optical fiber FB is attached to an edge of the interface structure HD2 and the core CFB of the optical fiber FB is oriented to direct to the optical component OP2. The optical signal from the optical fiber may travel in the optical component OP2 of the interface structure HD2 in a first direction, turn to travel in a second direction by the optical component OP1, pass through the lens member 218C and reach the optical transmission structure 212 of the photonic die 210.

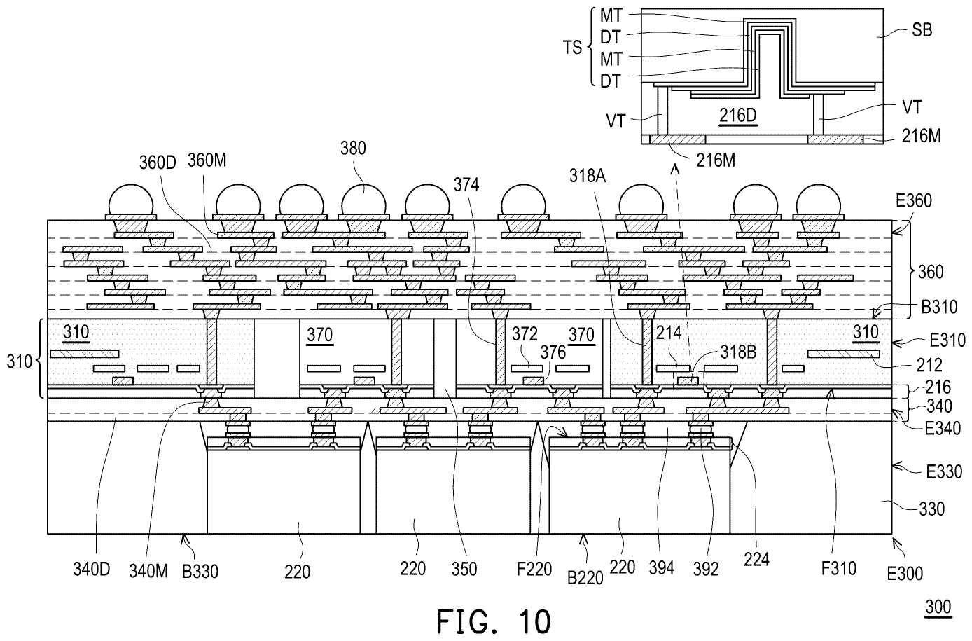

FIG. 10 schematically illustrates a cross-sectional view of a semiconductor package in accordance with some embodiments of the disclosure. A semiconductor package 300 in FIG. 10 includes a photonic die 310, electronic dies 220, a first encapsulation insulation 330, a first redistribution circuitry structure 340, a second encapsulation insulation 350, a second redistribution circuitry structure 360, one or more local interconnect die 370 and conductive connectors 380. The photonic die 310 and the electronic dies 220 are disposed at opposite sides of the first redistribution circuitry structure 340. The first encapsulation insulation 330 is disposed on the first redistribution circuitry structure 340 at the same side as the electronic dies 220 to surround and laterally encapsulate the electronic dies 220. The second redistribution circuitry structure 360 and the first redistribution circuitry structure 340 are located at opposite sides of the photonic die 310. The local interconnect dies 370 are disposed between the second redistribution circuitry structure 360 and the first redistribution circuitry structure 340, and the second encapsulation insulation 350 is also disposed between the second redistribution circuitry structure 360 and the first redistribution circuitry structure 340 to fill the gaps between the local interconnect dies 370 and the photonic dies 310. The conductive connectors 380 are disposed on the second redistribution circuitry structure 360 and are configured to connect the semiconductor package 300 to an external device/apparatus.

The photonic die 310 includes an optical transmission structure 212, an electronic component structure 214 and an interconnect structure 216. The photonic die 310 is oriented that the front surface F310 faces the first redistribution circuitry structure 340. Here, the functions of optical transmission structure 212, the electronic component structure 214 and the interconnect structure 216 may refer to the descriptions of the embodiment of FIG. 2 and be not reiterated. In the embodiment, the photonic die 310 further includes one or more through substrate via 318A. The through substrate via 318A extends through the photonic die 310 to establish the electrical transmission path between the front surface F310 of the photonic die 310 and the back surface B310 of the photonic die 310. The interconnect structure 216 of the photonic die 310 is electrically connected to the first redistribution circuitry structure 340 and the through substrate via 318A is electrically connected between the interconnect structure 216 of the photonic die 310 and the second redistribution circuitry structure 360. Therefore, the photonic die 310 may electrically connected to both the first redistribution circuitry structure 340 and the second redistribution circuitry structure 360.

In the embodiment, the photonic die 310 further includes one or more embedded capacitor structure 318B. The embedded capacitor structure 318B is electrically connected to the electronic component structure 214. In some embodiments, the embedded capacitor structure 318B may be formed in the photonic die 310 during the BEOL of the semiconductor manufacturing process. In some embodiments, the embedded capacitor structure 318B as shown in the enlarged portion in FIG. 10 may include a stack structure TS of the metallic electrode layers MT and the dielectric layers DT. The stack structure TS may be formed in a trench of the semiconductor substrate SB of the photonic die 310. In addition, contact via structures VT may be formed in the dielectric layer 216D in the interconnect structure 216 to connect between the metal features 216M in in the interconnect structure 216 and the metallic electrode layers MT of the embedded capacitor structure 318B.

The outer edge E310 of the photonic die 310 is exposed at the edge E300 of the semiconductor package 300, which enables the edge coupling with an external optical device such as an optical fiber. The photonic die 310 is arranged along the periphery of the semiconductor package 300 that has a wafer-level or panel-level size and the photonic die 310 includes multiple optical transmission structures 212 arranged along the periphery of the semiconductor package 300. Accordingly, the photonic die 310 may provide plenty of optical I/O channels along the periphery of the semiconductor package 300, which is beneficial to an application with a high bandwidth requirement.

The electronic dies 220 are disposed at a side of the first redistribution circuitry structure 340 opposite to the photonic die 310. The front surfaces F220 of the electronic dies 220 face the first redistribution circuitry structure 340 and the back surfaces B220 of the electronic dies 220 is further away from the first redistribution circuitry structure 340. The electronic dies 220 may involve the same function as the electronic dies 220 in the embodiment of FIG. 2. One of the electronic dies 220 may be electrically connected to the photonic die 310 through the first redistribution circuitry structure 340 and electrically connected between the photonic die 310 and others of the electronic dies 220. In addition, the electronic dies 220 may be electrically connected to one another through the first redistribution circuitry structure 340. In the embodiment, the electronic dies 220 are disposed on first redistribution circuitry structure 340 by implementing a die bonding process. A bonding structure 392 may be disposed between the interconnect structure 224 of the electronic die 220 and the first redistribution circuitry structure 340, and an underfill structure 394 may be formed between the electronic die 220 and the first redistribution circuitry structure 340 to surround and encapsulate the bonding structure 392. The bonding structure 392 may include microbumps. In some embodiments, the electronic die 220 and the first redistribution circuitry structure 340 may be bonded to each other through a metal-to-metal and dielectric-to-dielectric bonding technique, such that the interconnect structure 224 of the electronic die 220 may be in direct contact with the first redistribution circuitry structure 340 and the underfill structure 394 may be omitted.

The first encapsulation insulation 330 is disposed on the first redistribution circuitry structure 340 at the same side as the electronic die 220 to laterally encapsulate the electronic dies 220. The outer edge E330 of the first encapsulation insulation 330 extends to the edge E300 of the semiconductor package 300 and is coplanar with an outer edge E340 of the first redistribution circuitry structure 340 and the outer edge E310 of the photonic die 310. In addition, the surface B330 of the first encapsulation insulation 330 may be co-leveled with the back surfaces B220 of the electronic dies 220.

The local interconnect dies 370 are disposed at the same level as the photonic die 310, i.e. are disposed between the first redistribution circuitry structure 340 and the second redistribution circuitry structure 360. Each of the local interconnect dies 370 includes an electronic component structure 372, one or more through substrate via 374 and one or more embedded capacitor structure 376 formed in/on a semiconductor substrate such as a silicon substrate. The embedded capacitor structure 376 may have similar designed as the embedded capacitor structure 318B. The local interconnect die 370 may be known as a local silicon interconnect (LSI) and electrically connected between two or more of the electronic dies 220 through the first redistribution circuitry structure 340. In other words, the local interconnect die 370 may establish the interconnect of electric signals between two or more electronic dies 220, which helps to optimize the performance of the semiconductor package 300.

The second encapsulation insulation 350 is disposed between the first redistribution circuitry structure 340 and the second redistribution circuitry structure 360 to fill the gaps between the photonic die 310 and the local interconnect dies 370. In some embodiments, the first encapsulation insulation 330 and the second encapsulation insulation 350 may be made of the same material such as a molding compound, or the like. In FIG. 10, the encapsulation insulation 350 is disposed at the inner side of the photonic die 310 without being exposed at the edge of the semiconductor package 300, but the disclosure is not limited thereto.

The second redistribution circuitry structure 360 is disposed at the back surface B310 of the photonic die 310. The outer edge E360 of the second redistribution circuitry structure 360 is coplanar with the outer edge E330 of the first encapsulation insulation 330, the outer edge E340 of the first redistribution circuitry structure 340 and the outer edge E310 of the photonic die 310. The first redistribution circuitry structure 340 and the second redistribution circuitry structure 360 may be fabricated by using the same technique which embeds metal features in a dielectric structure to establish various electric transmission routing paths for the semiconductor package 300. For example, the first redistribution circuitry structure 340 includes a dielectric structure 340D and one or more layers of metal features 340M embedded in the dielectric structure 340D, in which the metal features 340M may include metal line features and metal via feature connecting between different layers of the metal line features. Similarly, the second redistribution circuitry structure 360 includes a dielectric structure 360D and one or more layers of metal features 360M embedded in the dielectric structure 360D, in which the metal features 360M may include metal line features and metal via feature connecting between different layers of the metal line features.

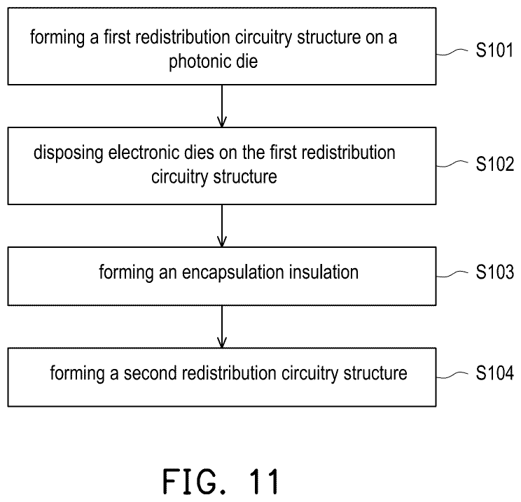

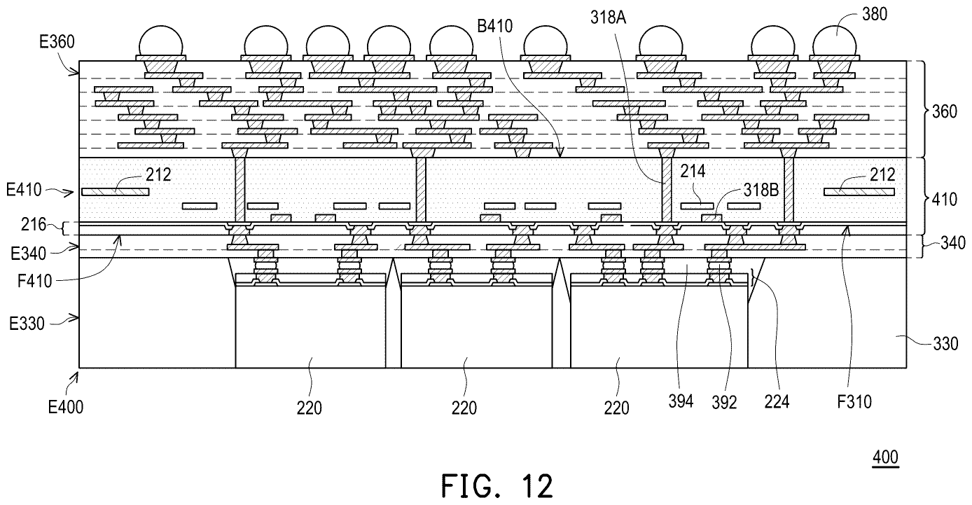

FIG. 11 schematically illustrates several steps of a method of fabricating a semiconductor package in accordance with some embodiments. In some embodiments, the semiconductor package 300 may be fabricated by implementing the following steps. Referring to FIG. 10, the photonic die 310 is temporally attached on a carrier substrate (not illustrated) in a manner that the front surface F310 of the photonic die 310 faces the carrier substrate. In addition, the local interconnect dies 370 are also temporally attached to carrier substrate in a manner that the front surface thereof faces the carrier substrate. The second encapsulation insulation 350 is then dispensed on the carrier substrate to fill the gaps between the photonic die 310 and the local interconnect dies 370. An integrated structure including the photonic die 310 and the local interconnect dies 370 integrated by the second encapsulation insulation 350 is then separated from the carrier substrate and the first redistribution circuitry structure 340 is formed on the integrated structure as indicated by the step S101 in FIG. 11. In the step S101, the first redistribution circuitry structure 340 is formed on the front surface F310 of the photonic die 310, such that the first redistribution circuitry structure 340 is electrically connected to the photonic die 310. The first redistribution circuitry structure 340 is also formed on the front surfaces of the local interconnect dies 370 and electrically connected to the local interconnect dies 370. In the embodiment, the first redistribution circuitry structure 340 is directly fabricated on the photonic die 310 and the local interconnect dies 370 without a bonding structure.

Referring to FIG. 10 and FIG. 11, the first redistribution circuitry structure 340 is formed on the photonic die 310 prior to the step S102 of disposing the electronic dies 212 on the first redistribution circuitry structure 340. In the embodiment, the electronic dies 220 are disposed on the first redistribution circuitry structure 340 by bonding the electronic dies 220 to the first redistribution circuitry structure 340 through the bonding structure 392. In addition, the underfill structure 394 is then formed to surround the bonding structure 392. After the bonding step, one or more of the electronic dies 220 may be electrically connected to the phonic die 310 through the first redistribution circuitry structure 340.

The first encapsulation insulation 330 is then formed on the first redistribution circuitry structure 340 in the step S103, such that the first encapsulation insulation 330 at least laterally surround the electronic dies 220 and the underfill structure 394. Thereafter, in the step S104, the second redistribution circuitry structure 360 is formed on the back surface B310 of the photonic die 310, such that the photonic die 310 is located between the first redistribution circuitry structure 340 and the second redistribution circuitry structure 360. Prior to forming the second redistribution circuitry structure 360, a process for finishing the through substrate via 318A in the photonic die 310 and the through substrate via 374 in the local interconnect die 370 is performed, such as a through substrate via (TSV) revealing process. The second redistribution circuitry structure 360 is formed on the photonic die 310 and the local interconnect die 370 and electrically connected to the through substrate via 318A in the photonic die 310 and the through substrate via 374 in the local interconnect die 370. Thereafter, the conductive connectors 380 are formed on the second redistribution circuitry structure 360 to finish the semiconductor package 300 as shown in FIG. 10.

FIG. 12 schematically illustrates a cross-sectional view of a semiconductor package in accordance with some embodiments of the disclosure. A semiconductor package 400 in FIG. 12 includes a photonic die 410, electronic dies 220, a first encapsulation insulation 330, a first redistribution circuitry structure 340, a second redistribution circuitry structure 360, and conductive connectors 380. The photonic die 410 and the electronic dies 220 are disposed at opposite sides of the first redistribution circuitry structure 340. The first encapsulation insulation 330 is disposed on the first redistribution circuitry structure 340 at the same side as the electronic dies 220 to surround and laterally encapsulate the electronic dies 220. The second redistribution circuitry structure 360 and the first redistribution circuitry structure 340 are located at opposite sides of the photonic die 310. The conductive connectors 380 are disposed on the second redistribution circuitry structure 360 and are configured to connect the semiconductor package 300 to an external device/apparatus.

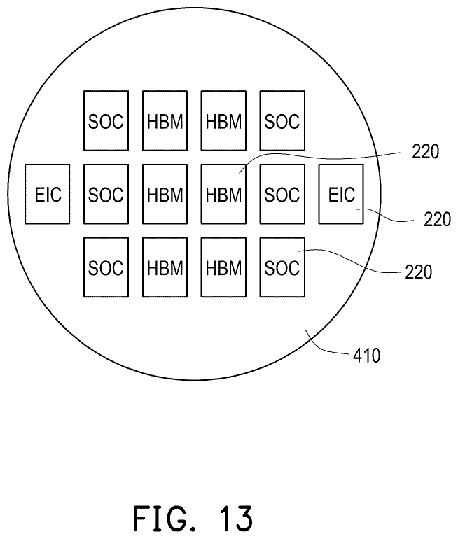

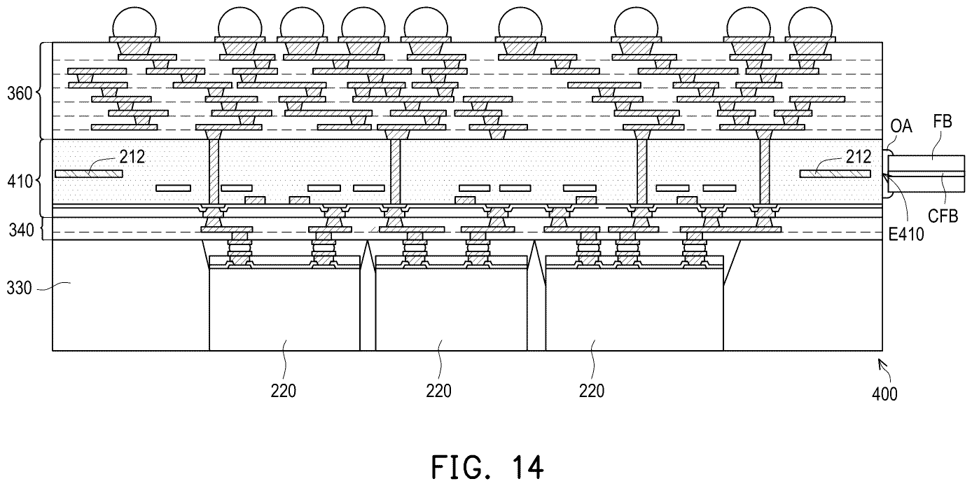

Specifically, the semiconductor package 400 is similar to the semiconductor package 300 depicted in FIG. 10, in which the difference between the semiconductor package 400 and the semiconductor package 300 mainly lies in that in the cross-sectional view, the semiconductor package 400 does not include the local interconnect die 370 and the second encapsulation insulation 350, and a lateral dimension of the photonic die 410 and a lateral dimension of the first redistribution circuitry structure 360 are substantially identical. In some embodiments, the photonic die 410 may have a circular top view shape as shown in FIG. 13 and the electronic dies 220 are disposed on the photonic die 410. The photonic die 410 shown in FIG. 13 may be in a wafer form that has a diameter of 300 mm or more. In addition, the electronic dies 220 disposed on the photonic die 410 may include electronic dies EIC, system-on-chip dis SOC, and memory dies HBM. In some embodiments, the semiconductor package 400 shown in FIG. 12 may be an implemented example of the cross-sectional view of the semiconductor package 100E in FIG. 5. In some embodiments, the semiconductor package 400 shown in FIG. 12 may be an implemented example of the cross-sectional view of the semiconductor package 100C in FIG. 3 taken along the connection portion 110C3. In some embodiments, the semiconductor package 400 shown in FIG. 12 may be an implemented example of the cross-sectional view of the semiconductor package 100D in FIG. 4 taken along the inner portion 110D2. The semiconductor package 400 may be fabricated by using a similar method of fabricating the semiconductor package 300 depicted in FIG. 11 while the steps for integrating the local interconnect dies 370 with the second encapsulation insulation 350 may be omitted in the case that the photonic die 410 has a top view size identical to the semiconductor package 400 as shown in FIG. 5.

Referring to FIG. 12 again, the photonic die 410 includes an optical transmission structure 212, an electronic component structure 214, an interconnect structure 216, one or more through substrate via 318A and one or more embedded capacitor structure 318B formed in/on a semiconductor substrate such as a silicon substrate. The semiconductor substrate of the photonic die may have a top view size identical to the semiconductor package 400. The photonic die 410 is oriented that the front surface F410 faces the first redistribution circuitry structure 340. Here, the functions of optical transmission structure 212, the electronic component structure 214 and the interconnect structure 216 may refer to the embodiment of FIG. 2 and the functions of the one or more through substrate via 318A and the one or more embedded capacitor structure 318B may refer to the embodiment of FIG. 10. The interconnect structure 216 of the photonic die 410 is interfaced with the first redistribution circuitry structure 340. The through substrate vias 318A extends through the semiconductor substrate of the photonic die 410 and establish an electrical connection between the electronic component structure 214 and the second redistribution circuitry structure 360.

In the embodiment, the outer edge E410 of the photonic die 410 is exposed at the edge E400 of the semiconductor package 400, which enables the edge coupling with an external optical device such as an optical fiber. In addition, the outer edge E410 of the photonic die 410, the outer edge E330 of the first encapsulation insulation 330 and the outer edge E340 of the first redistribution circuitry structure 340 and the outer edge E360 of the second redistribution circuitry structure 360 are continued with one another to construct the edge E400 of the semiconductor package 400. In some embodiments, the edge E400 of the semiconductor package 400 in the cross-sectional view may extend along a linear path which may be parallel to the thickness direction of the semiconductor package 400, oblique to the thickness direction of the semiconductor package 400, or curved with respect to the thickness direction of the semiconductor package 400.

In the embodiment, the electronic dies 220 are disposed on first redistribution circuitry structure 340 through a die bonding process. A bonding structure 392 may be disposed between the interconnect structure 224 of the electronic die 220 and the first redistribution circuitry structure 340. An underfill structure 394 may be formed between the electronic die 220 and the first redistribution circuitry structure 340 to surround the bonding structure 392. The bonding structure 392 may include microbumps. In some embodiments, the electronic dies 220 may be bonded to the first redistribution circuitry structure 340 through a metal-to-metal and dielectric-to-dielectric bonding technique, such that the interconnect structure 224 of the electronic die 220 may be in direct contact with the first redistribution circuitry structure 340.

The first encapsulation insulation 330 is disposed on the first redistribution circuitry structure 340 at the same side as the electronic dies 220 and laterally encapsulates the electronic dies 220. The second redistribution circuitry structure 360 is disposed at the back surface B410 of the photonic die 410. The first redistribution circuitry structure 340 and the second redistribution circuitry structure 360 may be fabricated by using the same technique which forms metal features in a dielectric structure of multiple dielectric layers to establish various electric transmission routing paths for the semiconductor package 400.

FIG. 14 schematically illustrates a scheme of coupling the photonic die in the semiconductor package with an optical fiber. As shown in FIG. 14, the semiconductor package 400 includes the photonic die 410 located between the first redistribution circuitry structure 340 and the second redistribution circuitry structure 360, and the electronic dies 220 disposed on the first redistribution circuitry structure 340 and laterally encapsulated by the first encapsulation insulator 330. In the embodiment, an optical fiber FB may be attached/connected to the outer edge E410 of the photonic die 410 though an optical adhesive OA. The optical fiber FB is positioned so that the optical coupling between the core CFB of the optical fiber FB and the optical transmission structure 212 formed in the photonic die 410 is optimized.

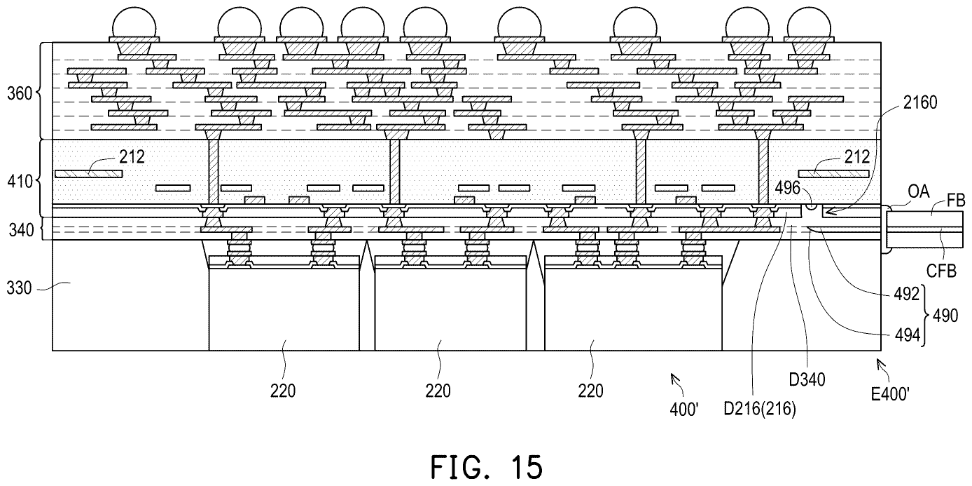

FIG. 15 schematically illustrates a scheme of coupling the photonic die in the semiconductor package with an optical fiber. As shown in FIG. 15, the semiconductor package 400′, having a design similar to the semiconductor package 400 depicted in FIG. 12, includes the photonic die 410 located between the first redistribution circuitry structure 340 and the second redistribution circuitry structure 360, and the electronic dies 220 disposed on the first redistribution circuitry structure 340 and laterally encapsulated by the first encapsulation insulator 330. The semiconductor package 400′ further includes an integrated optical structure 490 integrated in the dielectric structure D340 of the first redistribution circuitry structure 340. The integrated optical structure 490 includes a polymer waveguide portion 492, a reflector 494 and a lens 496.

The polymer waveguide portion 492 may be disposed between dielectric layers of the dielectric structure D340 of the first redistribution circuitry structure 340. The reflector 494 is located at the terminal of the polymer waveguide portion 492. The reflector 494 may have a curved surface, an oblique surface with respect to the polymer waveguide portion 492. In the embodiment, the interconnect structure 216 of the photonic die 410 includes a dielectric structure D216 that is patterned to have an opening 216O, the lens 496 is disposed in the opening 216O and a portion of the dielectric structure D340 of the first redistribution circuitry structure 340 extends in the opening 216O to cover the lens 496.

The material of the polymer waveguide portion 492 includes a polymer that is different from the polymer material for forming the dielectric structure D340 of the first redistribution circuitry structure 340. In some embodiments, the material of the polymer waveguide portion 492 may have high refractive index so that the optical transmission effect is desirable. The lens 496 is disposed between the photonic die 410 and the dielectric structure D340 of the first redistribution circuitry structure 340. A terminal of the polymer waveguide portion 492 opposite to the reflector 494 is exposed at the edge E400′ of the semiconductor package 400′. In the embodiment, the optical fiber FB is attached to the edge E400′ of the semiconductor package 400′ through an optical adhesive OA and the core CFB of the optical fiber FB is aligned with the terminal of the polymer waveguide portion 492 with an optimized optical coupling efficiency.

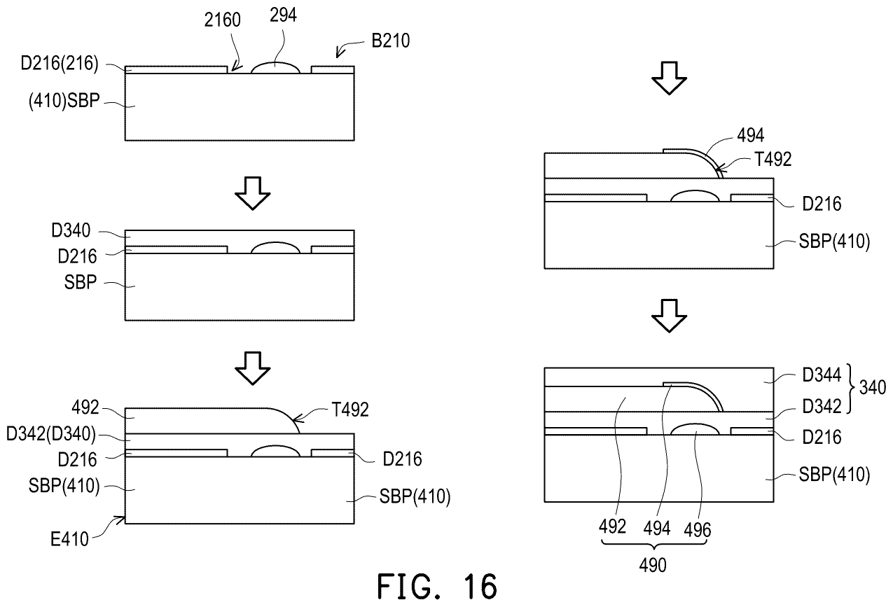

FIG. 16 schematically illustrates a method of fabricating the integrated optical structure depicted in FIG. 15. Referring to FIGS. 15 and 16, the dielectric structure D216 of the interconnect structure 216 in the photonic die 410 is patterned to form the opening 216O exposing the substrate SBP of the photonic die 410. The lens 294 is formed on the substrate SBP in the opening 216O. The dielectric structure D340 of the interconnect structure 340 is formed on the dielectric structure D216 and the lens 294 to fill the opening 216O. The polymer waveguide portion 492 is then formed on a partial dielectric portion D342 of the dielectric structure D340 of the interconnect structure 340 using a polymer material having high refractive index. The polymer waveguide portion 492 may extend to the outer edge E410 of the photonic die 410 and an inner terminal T492 of the polymer waveguide portion 492 is located corresponding to the lens 496. The inner terminal T492 of the polymer waveguide portion 492 has a curved surface or an oblique surface with respect to the extending direction of the polymer waveguide portion 492. Thereafter, the reflector 494 is formed on the curved surface or the oblique surface of the inner terminal T492. Further dielectric portion D344 of the dielectric structure D340 of the interconnect structure 340 to finish the integrated optical structure 490.

In view of the above, a semiconductor package in the embodiments of the disclosure include a photonic die and electronic dies integrated with one or more redistribution circuitry structure. The photonic die in the semiconductor package provides optical transmission structures along the periphery of the semiconductor package to enable multiple optical communication channels, which is preferable for a high band width design, a high-speed computing design, and/or a low noise design since the optical communication involves better performance than the electrical communication. The wafer/panel-leveled semiconductor package in the embodiments integrates the photonic die with system dies, memory dies or the like without bonding/attaching the photonic dies onto a substrate/circuitry board (such as PCB), which provides a simplified structure with a compact volume.

In some embodiments of the disclosure, a semiconductor package includes a first redistribution circuitry structure; a photonic die disposed on the first redistribution circuitry structure, wherein an outer edge of the first redistribution circuitry structure is coplanar with an outer edge of the photonic die; and electronic dies disposed on the first redistribution circuitry structure and electrically connected to the phonic die through the first redistribution circuitry structure. An encapsulation insulation may be further disposed on the first redistribution circuitry structure and surrounds the electronic dies. The encapsulation insulation is located between the photonic die and the electronic dies. A surface of the encapsulation insulation, a back surface of the photonic die and a back surface of the electronic dies are coplanar. An outer edge of the encapsulation insulation is coplanar with an outer edge of the photonic die. In some embodiments, the photonic die and the electronic dies are disposed at opposite sides of the first redistribution circuitry structure. A second redistribution circuitry structure may be further provided, and the photonic die is disposed between the first redistribution circuitry structure and the second redistribution circuitry structure. The outer edge of the photonic die, the outer edge of the first redistribution circuitry structure and the outer edge of the second redistribution circuitry structure are coplanar.

In some embodiments of the disclosure, a semiconductor package includes a first redistribution circuitry structure; a photonic die disposed on the first redistribution circuitry structure; electronic dies disposed on the first redistribution circuitry structure and electrically connected to the phonic die through the first redistribution circuitry structure, wherein the electronic dies and the photonic die are located at opposite sides of the first redistribution circuitry structure; and a first encapsulation insulation disposed on the first redistribution circuitry structure and surrounding the electronic dies, wherein an outer edge of the first encapsulation insulation is coplanar with an outer edge of the photonic die. A second redistribution circuitry structure is further provided, wherein the first redistribution circuitry structure and the second redistribution circuitry structure are located at opposite sides of the photonic die. A local interconnect die may be further disposed between the first redistribution circuitry structure and the second redistribution circuitry structure and electronically connecting to the electronic dies. A second encapsulation insulation may be further disposed between the photonic die and the local interconnect die. The photonic die includes a through substrate via extending through the photonic die and electrically connecting to the second redistribution structure. A lateral dimension of the photonic die and a lateral dimension of the first redistribution circuitry structure are substantially identical. The photonic die extends along a periphery of the semiconductor package.

In some embodiments of the disclosure, method of fabricating a semiconductor package includes forming a first redistribution circuitry structure on a photonic die, wherein an edge of the first redistribution circuitry structure is coplanar with an outer edge of the photonic die; electrically connecting electronic dies to the phonic die through the first redistribution circuitry structure; and forming an encapsulation insulation surrounding the electronic dies. The photonic die and the electronic dies are laterally encapsulated by the encapsulation insulation prior to forming the first redistribution circuitry structure. The first redistribution circuitry structure is formed on the photonic die prior to electrically connecting the electronic dies to the phonic die through the first redistribution circuitry structure by disposing the electronic dies on the first redistribution circuitry structure. A second redistribution circuitry structure may be further formed on the photonic die, wherein the photonic die is located between the first redistribution circuitry structure and the second redistribution circuitry structure. A through substrate via may be formed in the photonic die, wherein the through substrate via is electrically connected to the second redistribution circuitry structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor package, comprising:
a first redistribution circuitry structure;
a photonic die disposed on the first redistribution circuitry structure, wherein an outer edge of the first redistribution circuitry structure is coplanar with an outer edge of the photonic die; and
electronic dies disposed on the first redistribution circuitry structure and electrically connected to the phonic die through the first redistribution circuitry structure.

2. The semiconductor package of claim 1, further comprising an encapsulation insulation disposed on the first redistribution circuitry structure and surrounding the electronic dies.

3. The semiconductor package of claim 2, wherein the encapsulation insulation is located between the photonic die and the electronic dies.

4. The semiconductor package of claim 2, wherein a surface of the encapsulation insulation, a back surface of the photonic die and a back surface of the electronic dies are coplanar.

5. The semiconductor package of claim 2, wherein an outer edge of the encapsulation insulation is coplanar with an outer edge of the photonic die.

6. The semiconductor package of claim 1, wherein the photonic die and the electronic dies are disposed at opposite sides of the first redistribution circuitry structure.

7. The semiconductor package of claim 6, further comprising a second redistribution circuitry structure, and the photonic die is disposed between the first redistribution circuitry structure and the second redistribution circuitry structure.

8. The semiconductor package of claim 7, wherein the outer edge of the photonic die, the outer edge of the first redistribution circuitry structure and the outer edge of the second redistribution circuitry structure are coplanar.

9. A semiconductor package, comprising:
a first redistribution circuitry structure;
a photonic die disposed on the first redistribution circuitry structure;
electronic dies disposed on the first redistribution circuitry structure and electrically connected to the phonic die through the first redistribution circuitry structure, wherein the electronic dies and the photonic die are located at opposite sides of the first redistribution circuitry structure; and
a first encapsulation insulation disposed on the first redistribution circuitry structure and surrounding the electronic dies, wherein an outer edge of the first encapsulation insulation is coplanar with an outer edge of the photonic die.

10. The semiconductor package of claim 9, further comprising a second redistribution circuitry structure, wherein the first redistribution circuitry structure and the second redistribution circuitry structure are located at opposite sides of the photonic die.

11. The semiconductor package of claim 10, further comprising a local interconnect die disposed between the first redistribution circuitry structure and the second redistribution circuitry structure and electronically connecting to the electronic dies.

12. The semiconductor package of claim 11, further comprising a second encapsulation insulation disposed between the photonic die and the local interconnect die.

13. The semiconductor package of claim 10, wherein the photonic die comprises a through substrate via extending through the photonic die and electrically connecting to the second redistribution structure.

14. The semiconductor package of claim 9, wherein a lateral dimension of the photonic die and a lateral dimension of the first redistribution circuitry structure are substantially identical.

15. The semiconductor package of claim 9, wherein the photonic die extends along a periphery of the semiconductor package.

16. A method of fabricating a semiconductor package comprising:
forming a first redistribution circuitry structure on a photonic die, wherein an edge of the first redistribution circuitry structure is coplanar with an outer edge of the photonic die;
electrically connecting electronic dies to the phonic die through the first redistribution circuitry structure; and
forming an encapsulation insulation surrounding the electronic dies.

17. The method of claim 16, wherein the photonic die and the electronic dies are laterally encapsulated by the encapsulation insulation prior to forming the first redistribution circuitry structure.

18. The method of claim 16, wherein the first redistribution circuitry structure is formed on the photonic die prior to electrically connecting the electronic dies to the phonic die through the first redistribution circuitry structure by disposing the electronic dies on the first redistribution circuitry structure.

19. The method of claim 16, further comprising forming a second redistribution circuitry structure on the photonic die, wherein the photonic die is located between the first redistribution circuitry structure and the second redistribution circuitry structure.

20. The method of claim 19, further forming a through substrate via in the photonic die, wherein the through substrate via is electrically connected to the second redistribution circuitry structure.
